(19) United States
(12) Patent Application Publication
(10) Pub. No.: US 2011/0017275 A1
(43) Pub. Date: Jan. 27, 2011

(54) SOLAR PANEL BACK SHEET WITH IMPROVED HEAT DISSIPATION

(75) Inventors: Zuocheng Zhou, Shanghai (CN); Ruo Fei Zhao, Shanghai (CN); Shengcong Liufu, Shanghai (CN)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEUMOURS AND COMPANY, Wilimington, DE (US)

(21) Appl. No.: 12/935,070

(22) PCT Filed: Apr. 1, 2009
(86) PCT No.: PCT/US09/39051

§ 371 Date: Sep. 28, 2010

(30) Foreign Application Priority Data
Apr. 1, 2008 (CN) 200820088497.1

(51) Int. Cl. H01L 31/052

(52) U.S. Cl. 136/246

(57) ABSTRACT

The present invention discloses a solar panel comprising a front sheet, a back sheet and a photovoltaic circuit between the front and back sheets, wherein back sheet has an outer layer having a first surface and a second surface wherein the first surface faces the environment and has protrusions and the second surface is adjacent to the photovoltaic circuit.

### FIELD OF THE INVENTION

The present invention relates to a solar panel back sheet with improved heat dissipation. The back sheet has a first surface facing the surrounding environment, and a second surface placed adjacent to the photovoltaic circuit, wherein the first surface has a number of protrusions thereon.

### BACKGROUND OF THE INVENTION

With global warming, governments around the world are becoming increasingly demanding on energy conservation and emission reduction. Therefore, finding new energy sources to replace fossil fuels has become an urgent need.

Solar energy is a clean, pollution-free and inexhaustible source of energy. At present, solar energy is used by converting it into electricity primarily by means of solar panels. The electricity is then used to power electric water heaters, electric vehicles and satellite components.

Solar panels are photovoltaic devices generating electricity directly from light, more specifically, from sunlight. Current solar panels mainly comprise a back sheet, a photovoltaic circuit, encapsulation materials and a front sheet.

The encapsulation materials, such as polyethylene-vinyl acetate films, are used in solar panels to bond the front and back sheets. In a 150° C. hot press, molten polyethylene-vinyl acetate flows into voids in solar panels to encapsulate them. Conductive adhesives can also be used to interconnect solar cells.

The primary role of the front sheet in solar panels is to protect solar cells against mechanical impact and weathering. In order to make full use of light, the front sheet must have a high light transmittance in a certain range of the spectrum (for example, for polycrystalline silicon solar cells, the range is 400-1,100 nm). The front sheet of existing solar panels is typically made of glass (usually 3-4 mm thick low-iron tempered flint glass) or polymeric materials.

The primary role of the back sheet of solar panels is to protect the solar cells and encapsulation materials and/or conductive adhesives from moisture and oxidation. During assembly of solar panels, the back sheet is also used as mechanical protection to prevent scratches and as an insulator.

A solar cell is a photoelectric converting device. It receives sunlight and uses a spectrum of sunlight (e.g., sunlight with a wavelength shorter than 1,100 nm) for photoelectric conversion. This portion of solar energy absorbed by a solar cell goes through a photoelectric conversion process, and part of it is converted into electricity, and the rest of it is converted into heat energy. At the same time, a solar cell absorbs infrared light with a wavelength longer than 1,100 nm. This portion of infrared light energy is not converted into electricity, but is directly converted into heat. As a result, these two portions of heat energy are sufficient to rapidly raise the temperature inside a solar cell. During operation, an increase in internal temperature will significantly reduce the working efficiency of the solar cells.

In order to reduce the internal temperature of a solar panel, two cooling methods are currently used, namely, active cooling and passive cooling.

The active cooling method uses additional accessories and coolants to lower the temperature of a solar cell module. Such a method is effective, but also leads to high manufacturing and maintenance costs. In addition to the increased cost, a solar cell using such a cooling method has an increased volume and weight, which is a disadvantage when transporting and installing the module.

The passive cooling method uses a finned heat sink made of thermally conductive metal attached to a solar cell module to increase its surface area with the surrounding environment, thus cooling the module. However, such an additional heat sink also causes problems of increased solar panel cost and reduced portability in the field.

Therefore, there is a need for a solar panel with improved heat dissipation efficiency, which does not need additional accessories, and does not significantly increase the volume of the solar panel. Such a solar panel could be cost-effective, and conveniently carried and installed.

### SUMMARY OF THE INVENTION

A solar panel comprising a front sheet, a back sheet and a photovoltaic circuit disposed between the front sheet and the back sheet, wherein the back sheet has an outer layer having a first surface and a second surface wherein the first surface faces the environment and has protrusions disposed thereon and the second surface is adjacent to the photovoltaic circuit. The surface protrusions can be arranged in a regular or irregular pattern. The ratio of the distance between adjacent bottom edges of two adjacent protrusions to the distance between the vertices of the two adjacent protrusions is 0-0.99, preferably 0.1-0.8, more preferably 0.2-0.7.

### BRIEF DESCRIPTION OF THE DRAWINGS

The invention is illustrated by the following figures:

FIG. 1 is a vertical view of a solar panel back sheet with surface protrusions according to one embodiment.

FIG. 2 is a vertical view of a solar panel back sheet with surface protrusions according to another embodiment.

FIG. 3 is a vertical view of a solar panel back sheet with surface protrusions according to another embodiment.

FIG. 4 is a vertical view of a solar panel back sheet with surface protrusions according to another embodiment.

FIG. 5 is a vertical view of a solar panel back sheet with surface protrusions according to another embodiment.

FIG. 6 is a vertical view of a solar panel back sheet with surface protrusions according to another embodiment.

FIG. 7 is a vertical view of a solar panel back sheet with surface protrusions according to another embodiment.

FIG. 8 is a vertical view of a solar panel back sheet with surface protrusions according to another embodiment.

FIG. 9 is a vertical view of a solar panel back sheet with surface protrusions according to another embodiment.

FIG. 10 is a vertical view of a solar panel back sheet with surface protrusions according to another embodiment.

FIG. 11 is a cross-sectional view of a solar panel back sheet having a geometric pattern as shown in FIG. 1 according to one embodiment.

FIG. 12 is a cross-sectional view of a solar panel back sheet having a geometric pattern as shown in FIG. 2 according to another embodiment.

FIG. 13 is a cross-sectional view of a solar panel back sheet having a geometric pattern as shown in FIG. 1 according to yet another embodiment.

FIG. 14 is a cross-sectional view of a solar panel back sheet having a geometric pattern as shown in FIG. 4 according to one embodiment.

FIG. 15 is a cross-sectional view of a solar panel back sheet having a geometric pattern as shown in FIG. 5 and FIG. 9 according to yet another embodiment.

FIG. 16 is a cross-sectional view of a solar panel back sheet having a geometric pattern as shown in FIG. 8 according to one embodiment.

FIG. 17 is a cross-sectional view of a solar panel back sheet having a geometric pattern as shown in FIG. 6 according to one embodiment.

FIG. 18 is a cross-sectional view of a solar panel back sheet having a geometric pattern as shown in FIG. 6 according to another embodiment.

FIG. 19 is a cross-sectional view of a solar panel back sheet having a geometric pattern as shown in FIG. 7 according to one embodiment.

FIG. 20 is a cross-sectional view of a solar panel back sheet having a geometric pattern as shown in FIG. 10 according to one embodiment.

FIG. 21 is a schematic view of a solar panel.

### DETAILED DESCRIPTION OF THE INVENTION

The solar panel of the present invention comprises a front sheet, a back sheet and a photovoltaic circuit between the front sheet and the back sheet. Individual components of the solar panel are illustrated in detail in connection with the accompanying figures.

1. Back Sheet

There are no special restrictions to suitable materials for making the back sheet of the solar panel. Any materials suitable for making a solar panel back sheet can be used. Non-restrictive examples of the materials include a laminated TPE layer comprising fluoropolymers (such as polyfluoroethylene/polyethylene terephthalate/ethylene-vinyl acetate copolymer containing 1%-70% vinyl acetate); a laminated TPT layer comprising fluoropolymer (such as polyfluoroethylene/polyethylene terephthalate/fluoropolymer (such as polyfluoroethylene); and a laminated PET layer comprising polyethylene terephthalate/polyethylene terephthalate/polyethylene terephthalate.

In one embodiment, such a laminated layer is used that has a first and a second outer layer, the first outer layer having a first surface facing the surrounding environment and a second surface placed adjacent to a middle layer, wherein the first surface has a number of protrusions thereon. The two outer layers are polytrimethylene terephthalate with a middle layer laminated between the two outer layers of polytrimethylene terephthalate, wherein the middle layer comprises one or more layers of layer selected from a polytrimethylene terephthalate layer, a polyethylene-vinyl acetate layer, metal foil or combinations thereof.

In another embodiment, the middle layer is a polytrimethylene terephthalate layer coated with a silicon dioxide thin film.

In another embodiment, the middle layer is an aluminum foil.

In another embodiment, the middle layer is a multi-layer film of an aluminum foil and a polytrimethylene terephthalate layer coated with an alumina thin film.

There are many protrusions on the first surface of a solar panel back sheet of the invention. The surface protrusions are arranged in a regular or irregular pattern. As shown in FIG. 1, the protrusions may form many circular projections on the first surface. For example, each of the protrusions can be in a shape of a hemisphere (as shown in FIGS. 11 and 12), a cylinder (as shown in FIG. 13), a cone or a conical frustum.

The protrusions can also form projections with other shapes on the first surface of the back sheet, such as regular polygons (for example, triangles, squares, rectangles, regular pentagons and regular hexagons) or irregular polygons.

As shown in FIG. 6, in one embodiment, the protrusions form square projections on the first surface. The protrusions can be in the shape of prisms (as shown in FIG. 15), pyramids (as shown in FIG. 17) or pyramidal frusta (as shown in FIG. 18).

Although the protrusions shown in most of the figures are loosely arranged, they can also be densely arranged on the back sheet. For instance, the hemispheres as shown in FIGS. 1 and 10 can be densely arranged, i.e., where the distance between adjacent bottom edges of two adjacent protrusions is zero.

Although the protrusions shown in the figures are uniformly distributed, the present invention also includes embodiments in which the protrusions are not uniformly distributed. For instance, the protrusions can be discretely distributed in an irregular pattern.

In one embodiment, the protrusions on the first surface of the back sheet form a plurality of discrete islands, and the protrusions are uniformly distributed on each island.

The protrusions on the first surface of the solar panel back sheet preferably have a distribution density of 10⁴-10¹⁰/cm², more preferably 10⁵-10⁸/cm², and even more preferably 10⁵-10⁷/cm². If the distribution density of the protrusions is above 10¹⁰/cm², the cooling effect will be affected due to overcrowding of the protrusions. If the distribution density of the protrusions is lower than 10⁴/cm², the cooling effect will not be readily apparent due to limited increase in surface area. However, a non-apparent cooling effect does not mean there is no cooling effect at all.

The ratio of the distance between adjacent bottom edges of two adjacent protrusions to the distance between the vertices of two adjacent protrusions is 0-0.9, preferably 0.1-0.8, more preferably 0.2-0.7.

The shape of individual protrusions on the back sheet may not necessarily be the same. They can be different. In one embodiment, the protrusions on the first surface of the back sheet have two different shapes. In another embodiment, the protrusions on the back sheet are in two different shapes and are alternately arranged.

As used herein, the term “protrusions” is a general term that includes protrusions above the surface of the back sheet, and indentations below the surface of the back sheet, or a combination thereof for increasing the surface area.

There are no special restrictions to the height of the protrusion. Suitable height of the protrusion depends upon the specific requirements for the surface area. In one embodiment, the height of the protrusion is preferably 1-1,000 microns, more preferably 5-500 microns, most preferably 10-100 microns.

There are no special restrictions to the height-to-width ratio of the protrusion. Suitable height-to-width ratio depends upon the specific requirements for cooling. In one embodiment, the height-to-width ratio of the protrusion (which is the ratio of the height to the width or to the diameter of the bottom surface of the protrusion) is preferably 4:1-1:10, more preferably 1:1-1:4.

There are no special restrictions to the methods for making the protrusions. Protrusions can be made by any conventional method known in the art. In one embodiment, the back sheet is a laminated polymer layer. When making the back sheet, a polymer layer with preformed protrusions on its first surface, the surface that faces the environment, is used as an outer layer and laminated with other polymer layers. Examples of methods to pre-form the protrusions include embossing.

In order to meet requirements of different applications, for example, in order to increase the optical reflectivity of a solar panel back sheet to prevent photons from escaping out of the solar panel, the second surface of the first outer layer can be treated.

There are no special restrictions to suitable methods of surface treatment for the second surface of the first outer layer, as long as the application requirements are met (such as increasing the optical reflectivity of a solar panel back sheet to prevent photons from escaping out of the solar panel).

In one embodiment, surface treatment of the second surface of the first outer layer includes embossing the second surface in order to form protruding microstructures. The protruding microstructures can include continuous or discrete pyramids, pyramidal frusta, cones, conical frusta, and hemispheres.

The height of the protruding microstructures is usually 500 nm-500 μm, preferably 2-50 μm, and the height-to-width ratio is usually 4:1-1:10, preferably 1:1-1:4.

As used herein, the term “height of a protruding microstructure or height of a protrusion” refers to the vertical distance from the bottom surface center of a protrusion to the vertex (in the case of pyramids or cones), or to the upper surface (in the case of pyramidal and conical frusta), or to the highest point (in the case of hemispheres).

As described above, the back sheet can have continuous or discrete microstructures on the second surface. In a preferred embodiment, the back sheet has discretely arranged protruding microstructures on its second surface. The protruding microstructures are uniformly distributed on the surface at a density of 1-10¹⁰/cm², preferably 10⁴-10⁸/cm².

In an embodiment, the back sheet has discrete protruding microstructures on its second surface, and the protruding microstructures form a plurality of discrete islands. The protruding microstructures are continuously distributed on each island. The density can be about 1-10¹⁰/cm², preferably 10⁴-10⁸/cm².

Any conventional method can be used for making the protruding microstructures. For instance, a template with the desired indentations (such as an embossing roller) can be used for embossing microstructures on a layer that constitutes the second surface of the back sheet. With the microstructures facing outwards, the layer is then laminated with other layers to form the back sheet.

In one embodiment, hollow glass microspheres are spread and coated on the second surface of a polymer sheet to form protruding microstructures.

There are no special restrictions to the methods for making the laminated layer. Any conventional lamination method can be used. For instance, individual layers can be bonded together with a conductive adhesive, or laminated by thermocompression or extrusion lamination. Commonly used adhesives include ethylene-vinyl acetate copolymers and polyurethane adhesives.

The overall thickness of the laminated layer of this invention is 20-1,000 microns, preferably 50-800 microns, and more preferably 100-500 microns.

As shown in FIG. 21, the solar panel includes a back sheet 1, encapsulation layers 2 and 4, a photovoltaic circuit 3 and a front sheet 5. The back sheet 1 is usually made of a laminated layer, which has a number of protrusions on the surface (the first surface) that faces with surrounding environment. In one embodiment, the second surface of the back sheet adjacent to the photovoltaic circuit has been surface-treated (e.g., to form a surface texture by embossing so as to improve light utilization efficiency).

As used herein, the term “back sheet” of a solar panel refers to the cover sheet of a solar panel that is not facing sunlight.

As used herein, the term “front sheet” of a solar panel refers to the cover sheet of a solar panel that is facing sunlight. The front sheet has a first surface and a second surface. The first surface of the front sheet is a light receiving surface, facing the sun when in use. The second surface of the front sheet is placed adjacent to the photovoltaic circuit of a solar panel.

As used herein, the term “adjacent to the photovoltaic circuit” does not necessarily mean that the second surface of the front sheet and/or the back sheet is in direct contact with the photovoltaic circuit in a solar cell. There can be a layer of, for example, ethylene-vinyl acetate copolymer encapsulation material or a conductive adhesive between the photovoltaic circuit and the second surface of the front sheet and/or the back sheet.

As used herein, the term “solar panel” includes a variety of battery cells or battery modules that generate electricity when exposed to light. Depending upon the requirements of specific applications, a number of such battery cells or battery modules can be combined to obtain the desired electric power, voltage and current. Non-restrictive examples of such solar panels include solar panels comprising monocrystal silicon solar cells, polycrystalline silicon solar cells, nano-silicon solar cells, non-crystalline thin-film silicon solar cells, thin film CdTe solar cells, thin film CIGS solar cells, or dye-sensitized solar cells.

2. Front Sheet

Glass or polymer materials are used for making the front sheet of the solar panels. However, glass is preferred for it provides components with mechanical strength that a plastic back sheet can hardly provide. The primary role of the front sheet is to allow sunlight to penetrate through a solar panel, while protecting solar cell photovoltaic circuits from, for example, scratches.

There are no special restrictions to the thickness of the front sheet, as long as it allows sunlight to penetrate through a solar panel while protecting the solar cell photovoltaic circuit against mechanical impact, such as the impact of hailstones. In one embodiment, the front sheet is made of a plastic material with a thickness of 20-500 microns. The glass or plastic material suitable for making the front sheet of the solar panel of this invention can be selected from high transmittance materials. The transmittance of light with a wavelength in the range of 350-1,150 nm is generally higher than 88%, preferably higher than 92%, and most preferably higher than 96%. Nonrestrictive examples of such plastic material are fluoropolymers, such as perfluoroethylene-perfluoropropylene copolymers, ethylene-tetrafluoroethylene copolymers, tetrafluoroethylene-hexafluoropropylene-vinylidene fluoride copolymers, polyvinylidene fluoride, ethylene-chlorotrifluoroethylene copolymers and polychlorotrifluoroethylene; liquid crystal polymers; polyethylene terephthalate; polyethylene naphthalate; polymethyl methacrylate; ethylene-vinyl alcohol copolymers; polycarbonates; polyurethanes; and laminated materials made of two or more of these materials.

In order to increase the light transmittance of a solar panel, an antireflection film, also called a transmittance enhancing film, can be applied on the first surface of the front sheet to increase sunlight incidence.

There are no special restrictions to the antireflection film. If the front sheet is made of a plastic material, a suitable antireflection film can be a high transmittance material with a refractive index lower than the front sheet material. In one embodiment, the front sheet material is made of polyvinylidene fluoride, and the antireflection film is made of perfluoroethylene-perfluoropropylene copolymer. If the front sheet is made of glass, a suitable antireflection film can be a high transmittance material with a refractive index lower than glass. In another embodiment, the front sheet material is made of glass, and the antireflection film is made of magnesium fluoride and silica. This antireflection film can be made by a sol-gel method, vapor deposition, thermal spraying or magnetic sputtering. Transmittance of the glass made with these methods can be increased from 92% to a range of 94%-96%, or even higher.

In order to increase the light-trapping capability of a solar panel and thus increase overall output power, the surface of the front sheet adjacent to the photovoltaic circuit can be treated to increase the light reflectivity and to reduce the amount of light emitted out of the solar panel.

There are no special restrictions to the surface treatment methods of the front sheet, as long as the surface treatment methods can increase light reflectivity of the front sheet to prevent photons from escaping out of the solar panel.

In one embodiment, the front sheet is made of glass. The main surface of the front sheet adjacent to the photovoltaic circuit is embossed to form a number of protruding or indented microstructures. The protruding microstructures include continuous or discrete grooves, pyramids, pyramidal frusta, cones, conical frusta, hemispheres, or a combination of two or more of these geometric patterns.

The protruding microstructures are generally 500 nm-500 μm high, preferably 2-50 μm high. The height-to-width ratio is generally 4:1-1:10, preferably 1:1-1:4.

As described above, the front sheet of the present invention can have a number of continuous or discrete microstructures. In a preferred embodiment of the invention, a surface of the front sheet adjacent to the photovoltaic circuit has a number of discrete protruding microstructures, which are uniformly distributed on the main surface at a density of 1-10⁸/cm², preferably 10⁴-10⁷/cm².

In one embodiment, a main surface of the front sheet adjacent to the photovoltaic circuit has a number of discrete protruding microstructures, which form discrete islands, and are continuously distributed on each island.

In one embodiment, a main surface of the front sheet adjacent to the photovoltaic circuit has a number of discrete protruding microstructures, which form discrete islands, and the protruding microstructures are discretely and uniformly distributed on each island at a density of 1-10⁸/cm², preferably 10⁴-10⁷/cm².

The microstructures can be formed by any conventional method. When the front sheet is made of glass, the surface of the glass front sheet adjacent to the photovoltaic circuit (i.e., the second surface of the glass) can be treated to form a surface texture. There are no special restrictions to the methods of surface treating the glass front sheet, as long as they can increase the light reflectivity of the front sheet to prevent photons from escaping out of solar panels.

In one embodiment, surface treatment of the glass front sheet includes softening the glass front sheet by heating, and then embossing the main surface adjacent to the photovoltaic circuit (second surface) with a template to form a number of protruding microstructures. The protruding microstructures include continuous or discrete pyramids, pyramidal frusta, cones, conical frusta, hemispheres, regular or irregular grooves, or a combination of two or more of these geometric patterns.

In another embodiment, molten glass can be poured directly into a mold to form a glass plate having surface texture on its main surface (second surface). The surface texture includes continuous or discrete pyramids, pyramidal frusta, cones, conical frusta, hemispheres, regular or irregular grooves, or a combination of two or more of these geometric patterns.

In another embodiment, the glass surface texture is formed by chemical etching. Suitable chemical etching methods are known to those having ordinary skill in the art.

The protruding microstructures are generally 500 nm-500 μm high, preferably 2-50 μm high. The height-to-width ratio is generally 4:1-1:10, preferably 1:1-1:4.

As described above, the glass front sheet of the invention can have a number of continuous or discrete microstructures. In a preferred embodiment of the invention, a main surface of the glass front sheet adjacent to the photovoltaic circuit has a number of discrete protruding microstructures, which are uniformly distributed on the main surface at a density of 1-10⁸/cm², preferably 10⁴-10⁷/cm².

In one embodiment, a main surface of the glass front sheet adjacent to the photovoltaic circuit has a number of discrete protruding microstructures, which form discrete islands and are continuously distributed on each island.

In one embodiment, a main surface of the glass front sheet adjacent to the photovoltaic circuit has a number of discrete protruding microstructures, which form discrete islands and are discretely and uniformly distributed on each island at a density of 1-10⁸/cm², preferably 10⁴-10⁷/cm².

The surface protrusions on the second surface of the front sheet and the back sheet can be the same or different. Those having ordinary skill in the art can easily determine a suitable surface texture according to their expertise and the specific requirements of the battery cells, such as process requirements for embossed textures and battery plate thickness.

3. Solar Photovoltaic Circuit

There are no special restrictions to the types of suitable solar cell photovoltaic circuits. They can be made of, but are not limited to, monocrystalline silicon, polycrystalline silicon, nano-silicon, non-crystalline silicon, cadmium telluride or copper indium gallium selenium.

4. Polymer Encapsulation Layer

The solar panel uses conventional polymeric encapsulation materials for encapsulating the solar photovoltaic circuit and bonding the above-described front and back sheet to the solar photovoltaic circuit. Examples of suitable polymeric encapsulation materials include, for example, ethylene-vinyl acetate copolymers. The thickness of the polymeric encapsulation layer is generally 200-800 microns, preferably 250-750 microns, and more preferably 300-650 microns.

In one embodiment, a conductive adhesive is used to replace the polymeric encapsulation materials. The conductive adhesives can be any type of conductive adhesives commonly used in the art.

The solar panels can be made by any conventional methods known in the art. For example, a method of making is disclosed in Chinese Patent CN02143582.0 for manufacturing solar panels.

The present invention is further exemplified by the following illustrative examples.

### EXAMPLES

### Test Method

1. Method for Testing Solar Cell Output Power

Solar cell output power was determined by using a 3500 SLP component testing system (purchased from Spire Corporation, U.S.A.), and was compared with polycrystalline silicon solar cells assembled from ordinary front and back sheets.

2. Temperature of the Solar Panel Back Sheet

The temperature of the solar panel back sheet was determined by using a FLUKE572 infrared thermometer and was compared with polycrystalline silicon solar cells assembled from ordinary front and back sheets.

### Example 1

This example illustrates the cooling effect of a solar panel back sheet having an array of hemispherical protrusions on one of its surfaces with a tetragonal arrangement.

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated layer comprising a 100-micron-thick polytrimethylene terephthalate layer (Sorona® from DuPont, USA) that was laminated between first and second outer layers of 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet faces the surrounding environment, and was embossed by an embossing roller to form an array of hemispherical protrusions with a uniform tetragonal arrangement (as shown in FIGS. 1 and 11). The protrusions were uniformly distributed on the entire surface of the back sheet at a density of 1.6×10⁵/cm². Each hemispherical protrusion had a diameter of 12.5 microns. The distance between vertices of two adjacent hemispherical protrusions was 25 microns.

The back sheet temperature and solar panel output power were determined by using the above-described methods. The test results were 320.5° K. and 181.7 watts, respectively.

### Comparative Example 1

This comparative example is substantially the same as Example 1 except that a TPT (i.e., polyfluoroethylene/polytrimethylene terephthalate/polyfluoroethylene) back sheet was used, which had the same thickness, but did not have protruding microstructures on the surface that was facing the surrounding environment. With the same solar panel structure, the back sheet temperature and the solar panel output power were determined to be 325.2° K. and 180.3 watts/m², respectively.

### Example 2

This example illustrates the cooling effect of a solar panel back sheet having an array of hemispherical protrusions on one of its surfaces with a compact tetragonal arrangement.

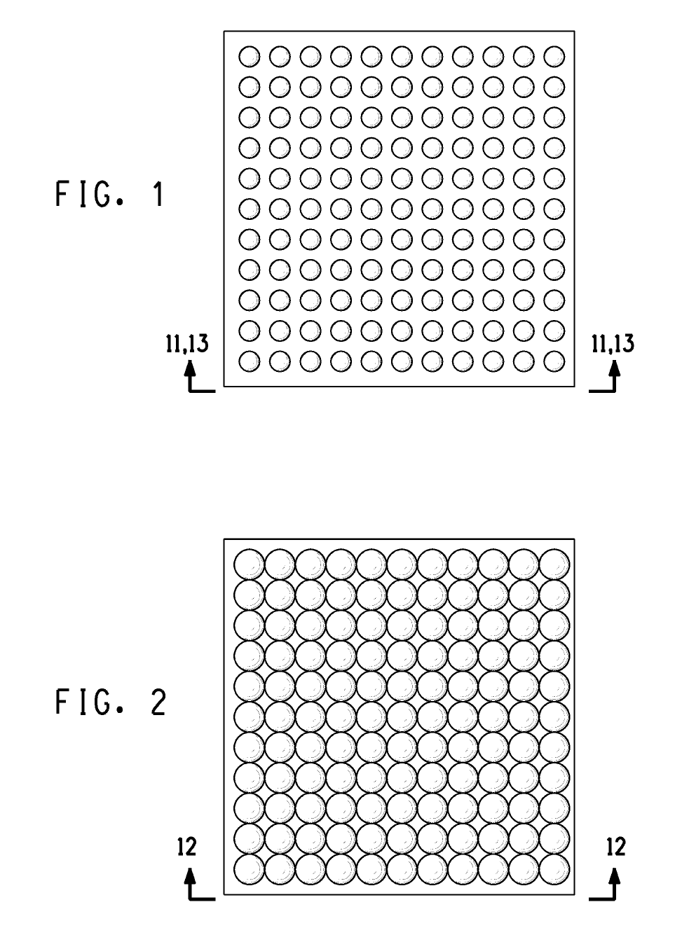

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated layer comprising a 100-micron-thick polytrimethylene terephthalate layer (Sorona® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of hemispherical protrusions with a uniform tetragonal arrangement. The protrusions were uniformly distributed on the entire surface of the back sheet (as shown in FIGS. 2 and 12) at a density of 6.4×10⁵/cm². Each hemispherical protrusion had a diameter of 12.5 microns. The distance between vertices of two adjacent hemispheres was 12.5 microns.

The back sheet temperature and solar panel output power were determined by using the above-described methods. The test results were 315.5° K. and 184.5 watts, respectively.

### Example 3

This example illustrates the cooling effect of a solar panel back sheet having an array of hemispherical protrusions on one of its surfaces with a compact hexagonal arrangement.

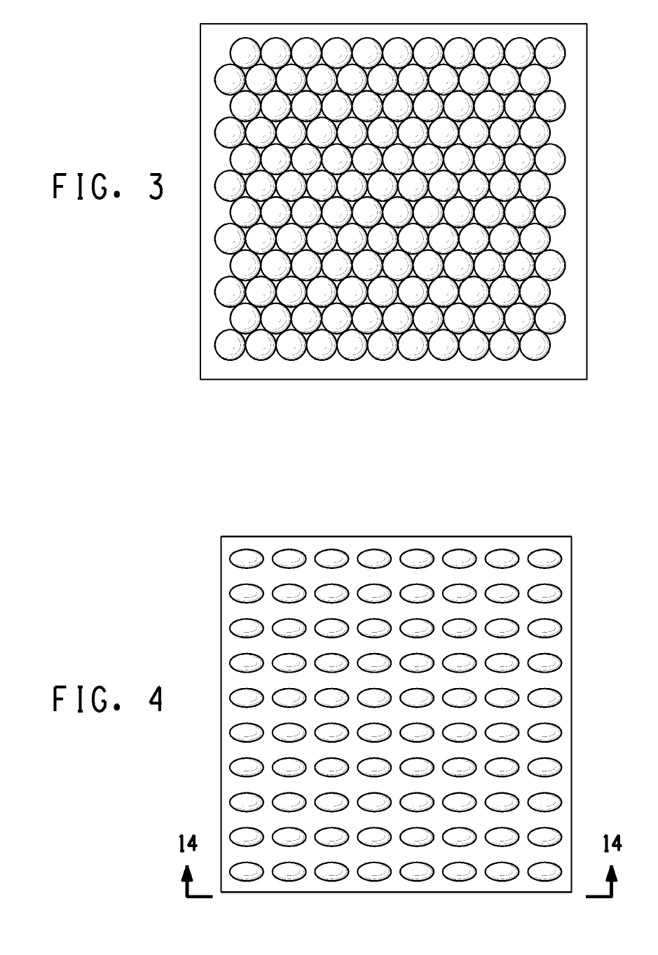

As shown in FIG. 21, a solar panel of this example comprises the following three components: a front sheet [5] (3.2-mm-thick tempered glass, purchased from Dongguan CSG Solar Glass Co., Ltd.), a photovoltaic circuit[3] being a polycrystalline silicon photovoltaic circuit (125×125×0.3 mm, 72 pieces interconnected in series) and a back sheet[1]. The back sheet was a laminated layer comprising a 100-micron-thick polytrimethylene terephthalate layer (Sorona® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of hemispherical protrusions with a uniform hexagonal arrangement. The protrusions were uniformly distributed on the entire surface of the back sheet (as shown in FIGS. 3 and 12) at a density of 6.4×10⁵/cm². Each hemispherical protrusion had a diameter of 12.5 microns. The distance between vertices of two adjacent hemispherical protrusions was 12.5 microns.

The back sheet temperature and solar panel output power were determined by using the above-described methods. The test results were 314.7° K. and 185 watts, respectively.

### Example 4

This example illustrates the cooling effect of a solar panel back sheet having a combined array of cylindrical and hemispherical protrusions on one of its surfaces with a tetragonal arrangement.

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated layer comprising a 100-micron-thick polytrimethylene terephthalate layer (Sorona® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of cylindrical and hemispherical protrusions with a uniform tetragonal arrangement. The protrusions were uniformly distributed on the entire surface of the back sheet (as shown in FIGS. 1 and 11) at a density of 1.6×10⁵/cm². Each protrusion had a diameter of 12.5 microns and a height of 20 microns. The distance between axes of two adjacent hemispheres was 25 microns.

The back sheet temperature and solar panel output power were determined by using the above-described methods. The test results were 313.9° K. and 185.5 watts, respectively.

### Example 5

This example illustrates the cooling effect of a solar panel back sheet having an array of cylindrical protrusions on one of its surfaces with a tetragonal arrangement.

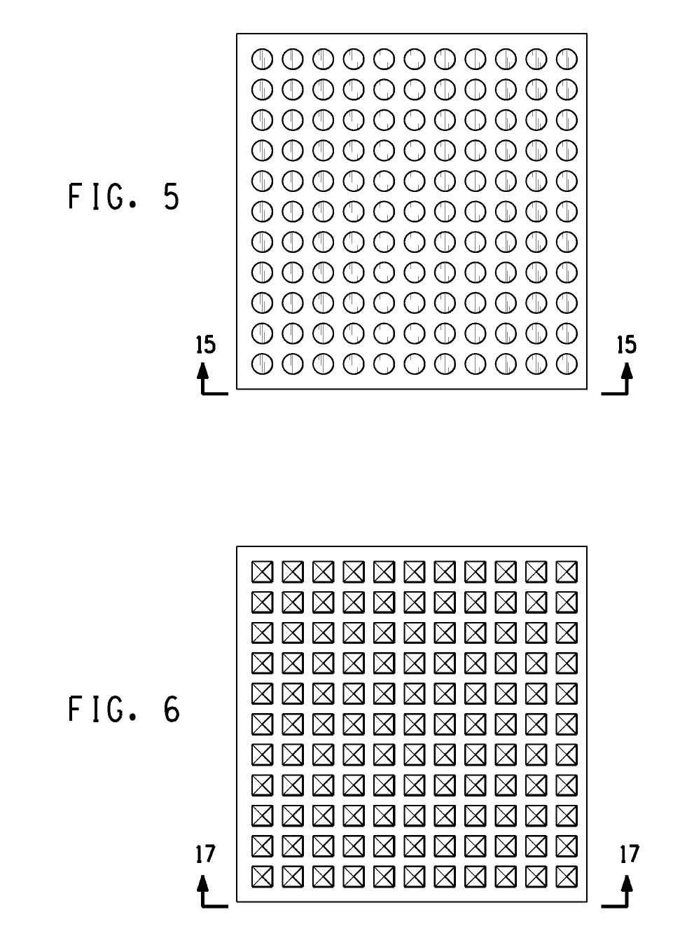

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated layer comprising a 100-micron-thick polytrimethylene terephthalate layer (Sorona® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of cylindrical protrusions with a uniform tetragonal arrangement. The protrusions were uniformly distributed on the entire surface of the back sheet (as shown in FIGS. 5 and 15) at a density of 1.6×10⁵/cm². Each cylindrical protrusion had a diameter of 12.5 microns and a height of 20 microns. The distance between axes of two adjacent cylindrical protrusions was 25 microns.

The back sheet temperature and solar panel output power were determined by using the above-described methods. The test results were 312.9° K. and 186 watts, respectively.

### Example 6

This example illustrates the cooling effect of a solar panel back sheet having an array of pyramidal protrusions on one of its surfaces with a compact arrangement.

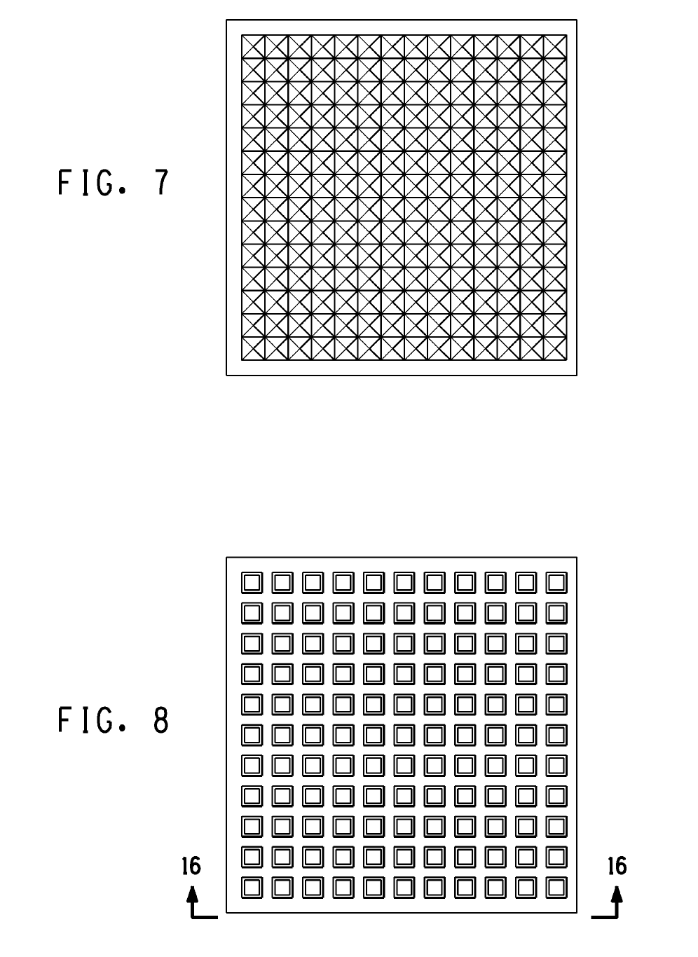

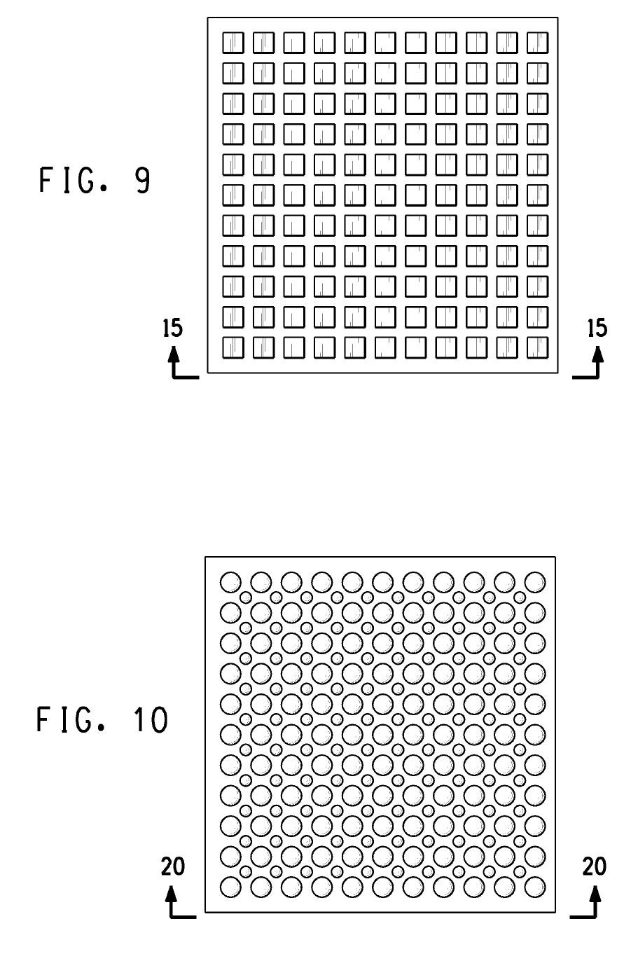

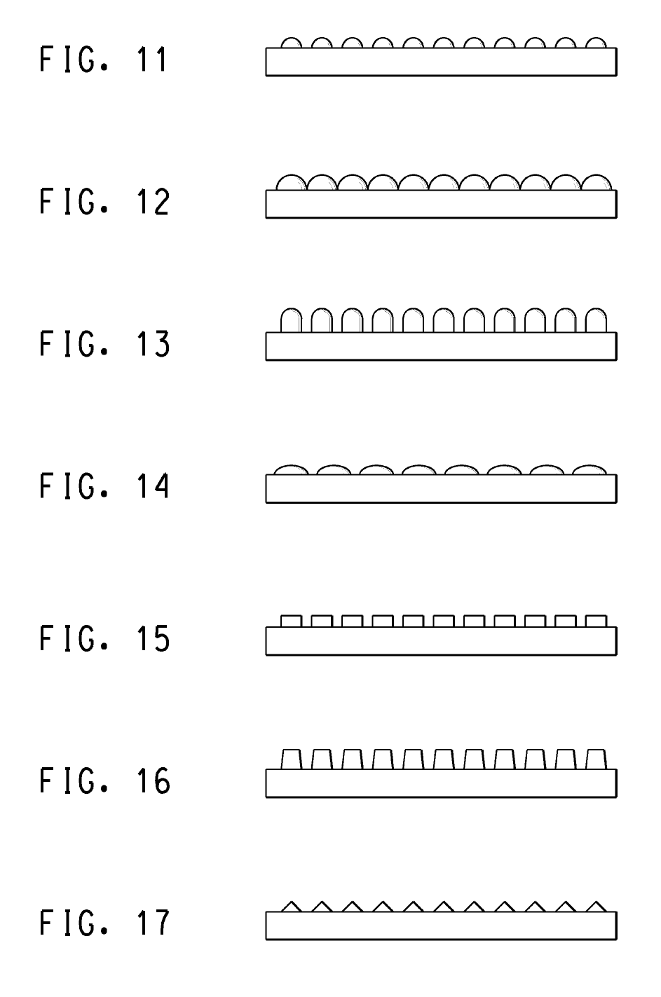

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated layer comprising a 100-micron-thick polytrimethylene terephthalate layer (Sorona® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of pyramidal protrusions with a uniform tetragonal arrangement. The protrusions were uniformly distributed on the entire surface of the back sheet (as shown in FIGS. 7 and 19) at a density of 6.4×10⁵/cm². Each pyramidal protrusion had a diameter of 12.5 microns and a height of 20 microns. The distance between vertices of two adjacent pyramidal protrusions was 12.5 microns.

The back sheet temperature and solar panel output power were determined by using the above-described methods. The test results were 309.0° K. and 187.9 watts, respectively.

### Example 7

This example illustrates the cooling effect of a solar panel back sheet having an array of conical protrusions on one of its surfaces with a compact tetragonal arrangement.

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated layer comprising a 100-micron-thick polyethylene terephthalate layer (Rynite® from DuPont, USA) that was laminated between two 25-micron-thick polytrimethylene terephthalate layers (Sorona® from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of conical protrusions with a compact tetragonal arrangement. The protrusions were uniformly distributed on the entire surface of the back sheet (as shown in FIGS. 5 and 19) at a density of 6.4×10⁵/cm². Each conical protrusion had a diameter of 12.5 microns and a height of 20 microns. The distance between vertices of two adjacent conical protrusions was 12.5 microns.

The back sheet temperature and solar panel output power were determined by using the above-described methods. The test results were 310.5° K. and 187.4 watts, respectively.

### Example 8

This example illustrates the cooling effect of a solar panel back sheet having an array of cylindrical protrusions on one of its surfaces with a random arrangement.

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated TPT layer comprising a 100-micron-thick polyethylene terephthalate layer (Rynite® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer (R767 Furui brand EVA encapsulation film for photovoltaic cells, purchased from Wenzhou Ruiyang Photovoltaic Materials Co., Inc.) by thermocompression. The first surface of the first outer layer of the back sheet, which faces the surrounding environment, was embossed by an embossing roller to form an array of cylindrical protrusions with a uniform tetragonal arrangement. The protrusions were uniformly distributed on the entire surface of the back sheet at a density of 1.6×10⁵/cm². Each cylindrical protrusion had a diameter of 12.5 microns and a height of 20 microns.

The back sheet temperature and solar panel output power were determined by using the above-described methods. The test results were 312.9° K. and 186 watts, respectively.

### Example 9

This example illustrates the cooling effect of a solar panel back sheet of this invention having an array of different sizes of hemispherical protrusions on one of its surfaces with an alternate arrangement.

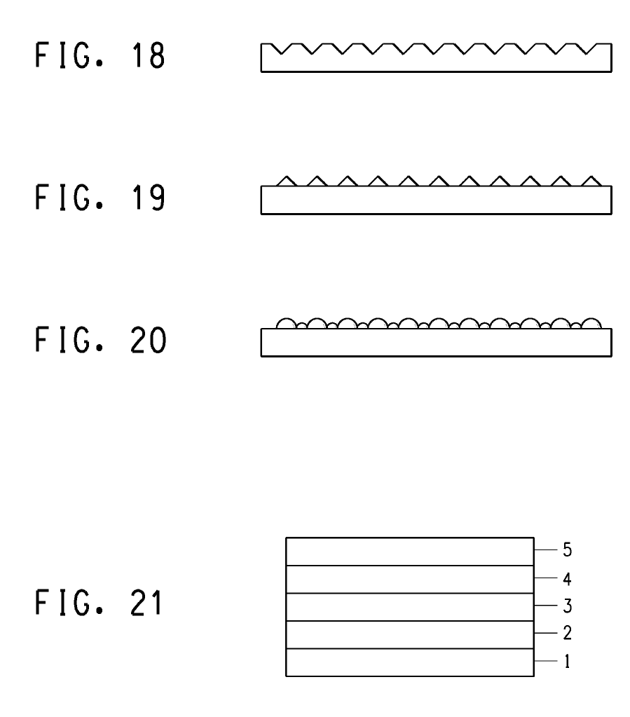

As shown in FIG. 21, a solar panel of this example comprises the following three components: a front sheet (3.2-mm-thick tempered glass, purchased from Dongguan CSG Solar Glass Co., Ltd.), a polycrystalline silicon photovoltaic circuit (125×125×0.3 mm, 72 pieces interconnected in series) and a back sheet. The back sheet was a laminated TPT layer comprising a 100-micron-thick polyethylene terephthalate layer (Rynite® from DuPont, USA) that was laminated between two 25-micron-thick polyfluoroethylene layers (Tedlar® PV2001 from DuPont, USA) by thermocompression under vacuum. The three components were laminated with two 700-micron-thick encapsulation layers of ethylene-vinyl acetate copolymer by thermocompression. The first surface of the first outer layer of the back sheet (i.e., the surface of the polyfluoroethylene layer), which faces the surrounding environment, was embossed by an embossing roller to form an array of hemispherical protrusions with a uniform tetragonal arrangement. The different sizes of protrusions were uniformly distributed on the entire surface of the back sheet (as shown in FIGS. 10 and 20) at a density of 1.6×10⁵/cm². Each large hemispherical protrusion had a diameter of 12.5 microns. The distance between the vertices of the two adjacent protrusions was 25 microns. Each small hemispherical protrusion had a diameter of 6.25 microns. The distance between the vertices of the two adjacent protrusions was 25 microns.

The back sheet temperature and solar panel output power were determined by using the above-described methods. The test results were 320 K and 182 watts, respectively.

As shown in the above examples, output power of the solar panel is effectively increased as a result of reducing the temperature inside the solar panel. By comparing the test results of Example 1 and Comparative Example 1, it can be seen that output power of solar panels can be increased by 0.78% by taking advantage of the cooling effect of the back sheets made according to the present invention.

What is claimed is:

1. A solar panel comprising a front sheet, a back sheet and a photovoltaic circuit disposed between the front sheet and the back sheet, wherein the back sheet has an outer layer having a first surface and a second surface wherein the first surface faces the environment and has protrusions and the second surface is adjacent to the photovoltaic circuit.

2. The solar panel as described in claim 1, characterized in that the protrusions are arranged in a regular or irregular pattern.

3. The solar panel as described in claim 1, characterized in that the ratio of the distance between adjacent bottom edges of two adjacent protrusions to the distance between the vertices of two adjacent protrusions is 0-0.9.

4. The solar panel as described in claim 3, characterized in that the ratio of the distance between adjacent bottom edges of two adjacent protrusions to the distance between the vertices of two adjacent protrusions is 0.1-0.8.

5. The solar panel as described in claim 1, characterized in that the protrusions are distributed on the back sheet at a density of 10⁴-10⁵/cm².

6. The solar panel as described in claim 5, characterized in that the protrusions are distributed on the back sheet at a density of 10⁵-10⁷/cm².

7. The solar panel as described in claim 1, characterized in that the back sheet has protruding microstructures on its second surface.

8. The solar panel as described in claim 7, characterized in that the protruding microstructures are selected from the group consisting of continuous or discrete pyramids, pyramidal frusta, cones, conical frusta and hemispheres.

9. The solar panel as described in claim 8, characterized in that the protruding microstructures have a height of 1 μm-1,000 μm.
